(19) United States
(12) Patent Application Publication
(10) Pub. No.: US 2008/0217268 A1
(43) Pub. Date: Sep. 11, 2008

(54) Frame system for an article storage apparatus

(75) Inventors: Mitsuru Yoshida, Osaka (JP); Yoshitaka Inui, Shiga (JP)

Correspondence Address: THE WEBB LAW FIRM, P.C., 700 KOPPERS BUILDING, 436 SEVENTH AVENUE, PITTSBURGH, PA, 15219, US

(73) Assignee: DAIFUKU CO., LTD., Osaka (JP)

(21) Appl. No.: 11/983,800

(22) Filed: Nov. 9, 2007

(30) Foreign Application Priority Data
Nov. 15, 2006 (JP) JP2006-30999400

(51) Int. Cl. H01L 21/67; B65D 85/00

(52) U.S. Cl. 211/41.18; 403/410; 206/710

(57) ABSTRACT

A frame system for an article storage apparatus which defines an article storage space therein, includes a first upper frame extending horizontally, a first lower frame extending horizontally, and at least one first connecting frame extending vertically and interconnecting the first upper frame and the first lower frame. The first upper frame has receiving bores formed therein through which elongate supports extend vertically when the elongate supports are attached to said first lower frame to suspend the first lower frame.

### BACKGROUND OF THE INVENTION

This invention relates to a frame system for an article storage apparatus which defines an article storage space therein.

Generally, a conventional frame system for an article storage apparatus is constructed, for example, of a plurality of vertical frames and a plurality of horizontal frames connected by brackets in a state of crossing each other. An article storage apparatus having such a frame structure is installed on the floor of a building (see JP 2004-59223, for example).

However, where, for example, this type of article storage apparatus is installed in a semiconductor plant, the apparatus may be suspended from the ceiling of a building or from a suspension support disposed in an upper location in the building. Such a suspension mode is necessary in order to install various processing equipment compactly in a limited space while securing working space for performing maintenance.

Specifically, a semiconductor plant has, installed therein, a plurality of processing units which perform various processes for manufacturing semiconductor substrates as processed objects, and a transport device for successively transporting containers storing the semiconductor substrates, as transported articles, from one of the processing units to another. A difference may occur in throughput of the processed objects between treating units adjacent each other on a transport path of the transport device. The above article storage apparatus may be installed in a space between the processing units for temporarily storing transported articles in the course of transport by the transport device between the processing units. It is thus possible to deal with the difference in throughput between the above processing units.

Where, as in the prior art, the article storage apparatus is installed on the floor, only a narrow space is available between the processing units. It is therefore difficult to do maintenance of each processing unit using this space. Thus, the article storage apparatus may be suspended from the ceiling of the building or from a suspension support device disposed in an upper location. In this way, the article storage apparatus may be installed by effectively using the limited space between the processing units, and at the same time a working space is secured between the article storage apparatus and the floor to facilitate a maintenance operation.

Where the article storage apparatus is suspended from and supported by the ceiling of the building or the like, it is conceivable to connect upper positions of the apparatus to elongate supports having upper ends thereof supported by the ceiling or the like. With this construction, however, connections between the vertical frames and horizontal frames must support the weight of all frames below the connecting locations and the weight of articles stored. To withstand the downward pulling force due to the large weight, the connections must have a greater connecting strength than the case where the article storage apparatus is installed on the floor. As a result, there is a drawback of complicating a connecting structure in each of the connecting locations between the plurality of frames.

In order to suspend and support the article storage apparatus from the ceiling of the building or the like without complicating the connecting structure of the connections of the frames as noted above, it is conceivable to arrange elongate suspension supports laterally outward of the article storage apparatus to extend to a large extent downward. The elongate supports have bearing portions projecting horizontally therefrom for receiving and supporting the weight of the article storage apparatus. However, with the elongate supports arranged as offset laterally outward, this construction has a disadvantage of an enlarged overall dimension in the transverse direction.

### SUMMARY OF THE INVENTION

The object of this invention is to alleviate at least one of the above-noted drawbacks of the prior art.

In one embodiment, s frame system for an article storage apparatus which defines an article storage space therein, comprises:

a first upper frame extending horizontally;

a first lower frame extending horizontally; and

at least one first connecting frame extending vertically and interconnecting said first upper frame and said first lower frame, said at least one first connecting frame being connected to said first upper frame with the at least one first connecting frame abutting a lower surface of said first upper frame, and connected to said first lower frame with the at least one first connecting frame abutting an upper surface of said first lower frame;

said first upper frame having receiving bores formed therein through which elongate supports extend vertically when said elongate supports are attached to said first lower frame to suspend the first lower frame.

Thus, when the article storage apparatus is suspended and supported by the elongate supports, the elongate supports having upper ends thereof supported by a ceiling or the like are passed vertically through the receiving bores formed in the first upper frame, and the first lower frame may be suspended and supported by the elongate supports. That is, the first upper frame, first connecting frame and first lower frame connected together can be suspended and supported by the elongate supports through the first lower frame.

With this construction, the weight of the first upper frame is suspended and supported by the elongate supports through the first connecting frame and first lower frame. In the connecting location of the first upper frame and first connecting frame, for example, the weight of the first upper frame needs only to be received and borne by an upper end surface of the first connecting frame. Similarly, in the connecting location of the first connecting frame and first lower frame, the weight of the first upper frame and first connecting frame needs only to be received and borne by an upper surface of the first lower frame.

The elongate supports are arranged to extend through the receiving bores formed in the first upper frame. Thus, the elongate supports are located in substantially the same position in the transverse direction as the first upper frame, instead of protruding laterally outward. This arrangement can avoid the overall size enlarging in the transverse direction.

When the entire article storage apparatus is installed on the floor, the weight of the entire apparatus is received and borne by the floor, for example, through the first lower frame. Thus, the connecting structure of the frames does not become very complicated. When the entire article storage apparatus is installed on the floor, there is no need for such components as suspension supports. The transverse dimension of the apparatus is never enlarged.

Thus, according to the characteristic construction noted above, the frame system for an article storage apparatus can be installed in various ways without such drawbacks as a very complicated structure for connecting the frames together and an enlarged overall dimension in the transverse direction.

### BRIEF DESCRIPTION OF THE DRAWINGS

FIG. 1 is a schematic plan view showing an installation state of article storage apparatus;

FIG. 2 is a perspective view of an article storage apparatus;

FIG. 3 is a view in vertical section of the article storage apparatus;

FIG. 4 is a perspective view showing a construction of a support transporting device;

FIG. 5 is a side view showing a frame structure;

FIG. 6 is a plan view showing the frame structure;

FIG. 7 is a view showing a frame connecting state;

FIG. 8 is a view showing a frame connecting state,

FIG. 9 is a front view in vertical section of the article storage apparatus;

FIG. 10 is a perspective view showing a support structure for an article storage tray;

FIG. 11 is a view showing vertical movement of a positioning member;

FIG. 12 is a side view in vertical section of a positioning member arranging portion;

FIG. 13 is a plan view of the positioning member arranging portion;

FIG. 14 is a plan view showing a position regulating state of the positioning member;

FIG. 15 is a sectional view showing engagement between a positioning bore and a positioning projection; and

FIG. 16 is an explanatory view showing depositing and delivery operations.

### DETAILED DESCRIPTION OF PREFERRED EMBODIMENTS

Article storage apparatus according to this invention will be described hereinafter with reference to the drawings. The entire disclosure of U.S. Pat. No. 7,210,589 in the name of the same applicant is incorporated herein by reference.

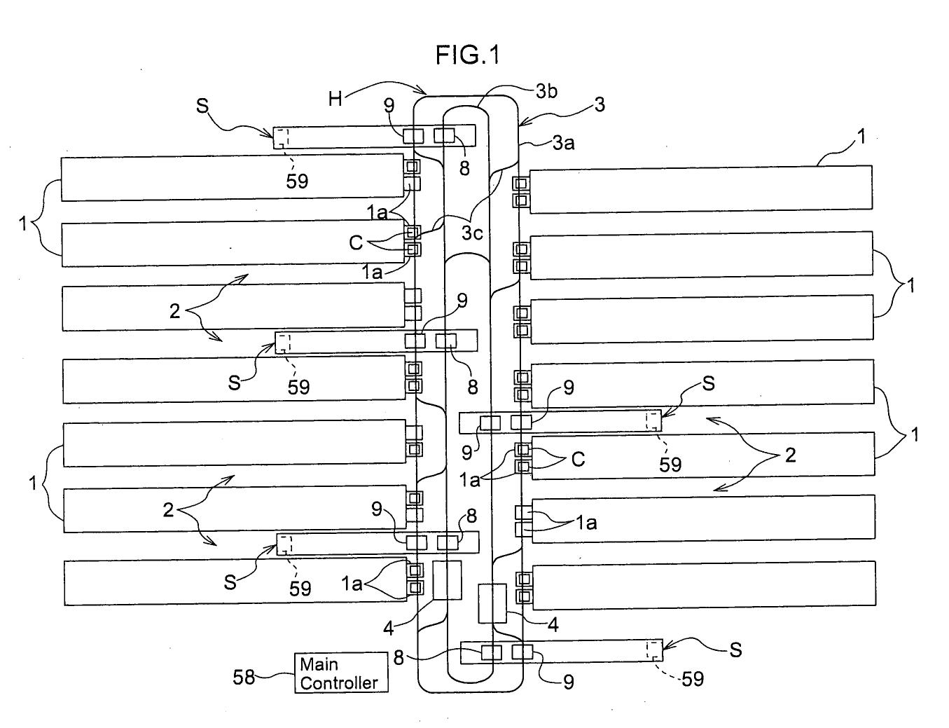

As shown in FIG. 1, a plurality of processing units 1 for performing various processes on semiconductor substrates are arranged in two rows in a semiconductor plant which is a cleanroom. Each processing unit 1 is formed sideways long in plan view, and has a pair of support tables 1a arranged at one end in the longitudinal direction thereof for receiving article storage containers C storing semiconductor substrates. The processing units 1 in each row are spaced from one another, with the support tables 1a located at the same end. The two rows are arranged with the respective support tables 1a opposed to each other. A space 2 formed between each adjoining pair of processing units 1 is used as maintenance space for performing maintenance of these processing units 1.

In order to perform various processes on semiconductor substrates, an article transport device H is provided as a container transporting device for successively transporting the article storage containers C to and from the processing units 1. A difference may occur in throughput of semiconductor substrates between processing units 1 adjacent each other on a transport path of the transport device H. Thus, a plurality of (five in this embodiment) article storage apparatus S for temporarily storing the article storage containers C are arranged at appropriate intervals along the transport path of article transport device H.

As shown in FIGS. 1, 2, and 3, the article transport device H includes a looped guide rail 3 installed on the ceiling to extend around and above the plurality of processing units 1 arranged in two rows as noted above, article transport vehicles 4 acting as mobile bodies supported to be movable along the guide rail 3, and an article gripper 5 vertically movably provided on each article transport vehicle 4. The article gripper 5 is switchable between a hold state for holding in suspension an article storage container C to be transported by gripping a gripped portion Ca on the top of the container C, and a release state for canceling the hold state.

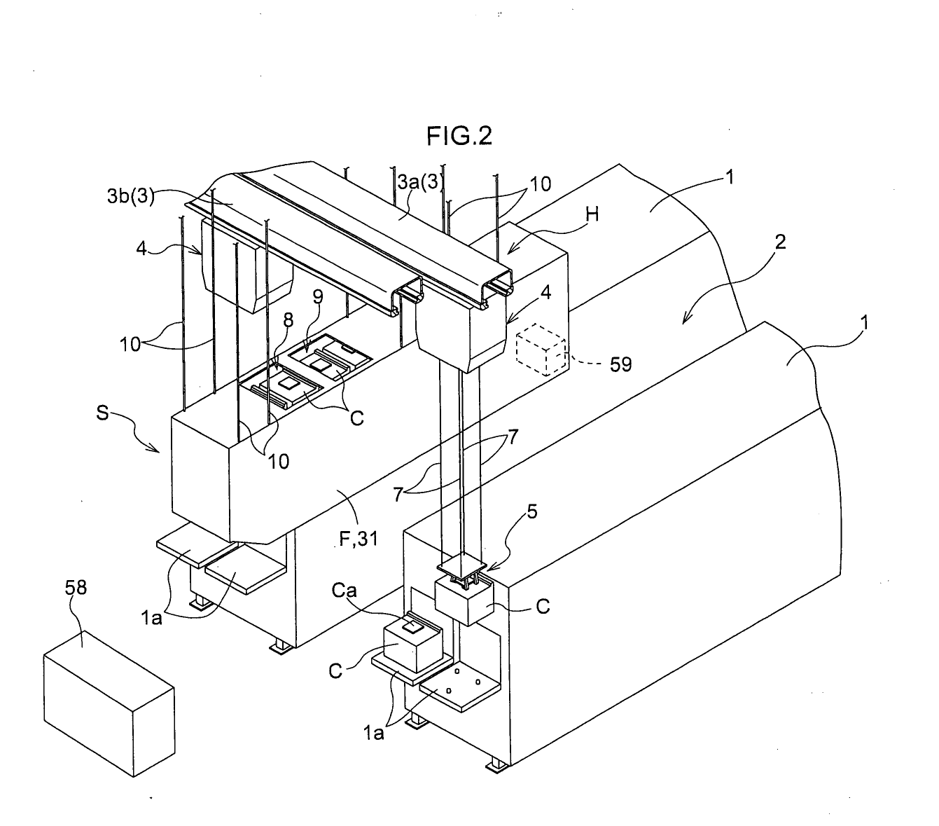

The article transport device H constructed as described above carries out a lifting operation for lifting the article gripper 5 gripping an article storage container C from a support table 1a of a processing unit 1 as shown in FIG. 2, a moving operation for moving the article transport vehicle 4 along the guide rail 3, and a lowering operation for lowering the gripped article storage container C to a support table 1a of a processing unit 1. In this way, the article transport device H can transport article storage containers C successively to the plurality of processing units 1.

Briefly, with the article transport vehicle 4 standing still in a target stop position opposed to a support table 1a of a processing unit 1, the article gripper 5 is vertically moved by winding and unwinding wires 7. Thus, the article gripper 5 gripping an article storage container C may be raised to pick up the article storage container C from an article storage tray 6 of an article storage apparatus S or a support table 1a of a processing unit 1. The article gripper 5 gripping an article storage container C may be lowered to place the article storage container C on an article storage tray 6 of an article storage apparatus S or a support table 1a of a processing unit 1.

As shown in FIGS. 1 and 2, the guide rail 3 of article transport device H has a double loop construction including an outer loop portion 3a extending over the support tables 1a of the processing units 1 and delivery ports 9 of the article storage apparatus S, and an inner loop portion 3b extending over deposition ports 8 of the article storage apparatus S. The guide rail 3 further includes transfer path portions 3c for allowing the article transport vehicles 4 to move from the outer loop portion 3a to the inner loop portion 3b and vice versa. The two article transport vehicles 4 are provided to move along this guide rail 3.

Next, the article storage apparatus S will be described.

As shown in FIG. 2, each article storage apparatus S is formed horizontally long in plan view, and is suspended from the ceiling by a plurality of hanger bolts 10 acting as elongate supports. The longitudinal direction of the article storage apparatus S extends along the longitudinal direction of the processing units 1. A vacant space is formed between the bottom of article storage apparatus S and the floor. The hanger bolts 10 may be formed of metal such as iron, steel or aluminum, or may be formed of a composite material. The hanger bolts 10 may have a circular, quadrilateral or other polygonal section. In this specification, “elongate” desirably means that the length in the longitudinal direction is two or more times the width across the longitudinal direction, and more desirably means that the length in the longitudinal direction is 5 or more times or 10 or more times the width across the longitudinal direction.

Next, the construction of the article storage apparatus S and its frame structure will be described.

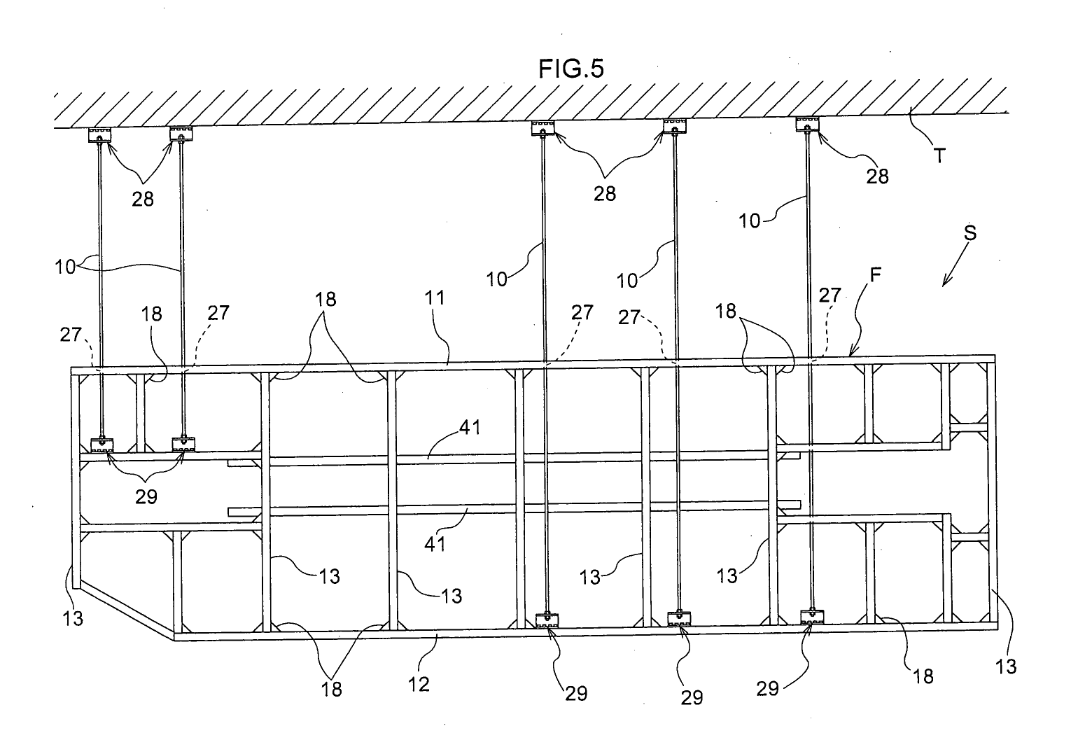

As shown in FIGS. 5, 6 and 9, the frame structure F of the article storage apparatus S includes a plurality of frames connected to define a substantially rectangular parallelepiped space for article storage. That is, upper horizontal frames 11, lower horizontal frames 12, and vertical connecting frames 13 connecting these frames 11 and 12 are formed long, respectively. The connecting frames 13 are connected to the upper frames 11 in a state of abutment on the lower surfaces of upper frames 11, and connected to the lower frames 12 in a state of abutment on the upper surfaces of lower frames 12. These lower frames 12 and upper frames 11 connected to the connecting frames 13 constitute a pair of right and left side frames 14 and 15 which are interconnected by a plurality of joining frames 16 extending transversely.

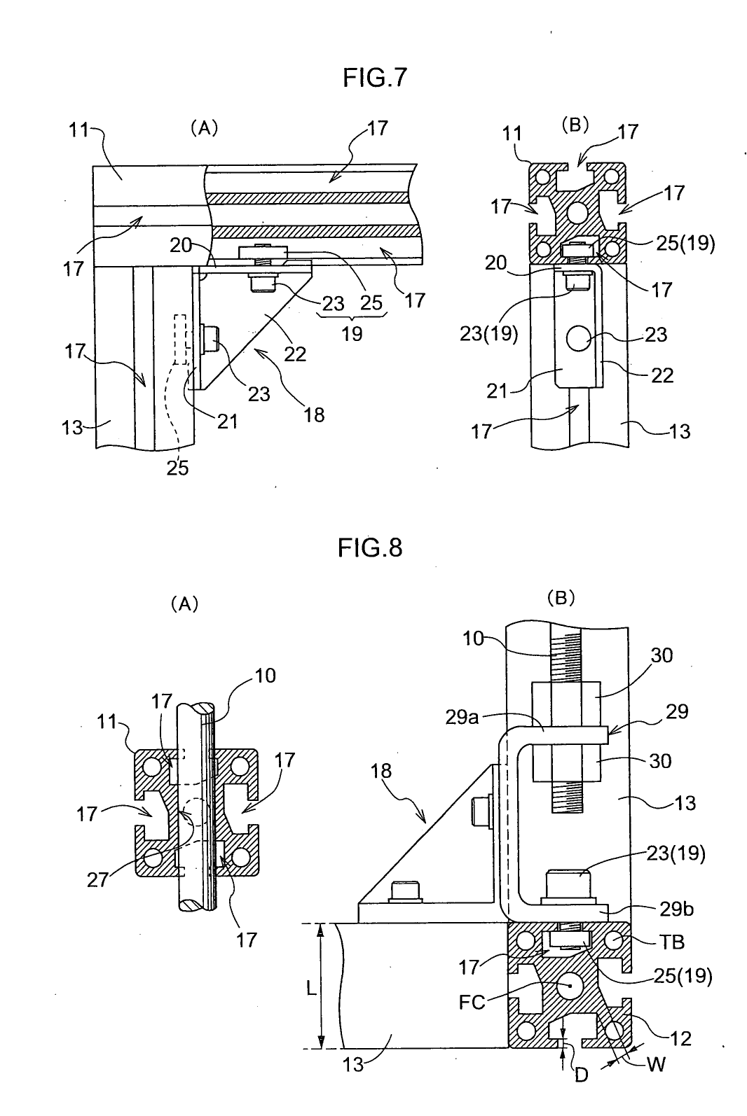

As shown in FIGS. 7 and 8, each of lower frames 12, upper frames 11, connecting frames 13 and joining frames 16 is rectangular when seen in vertical section, and has an engaging groove 17 (also called a fitting groove) formed in each of the four surfaces to have a back portion broader than an entrance portion. A connector 18 having a contact surface 21 and a contact surface 22 extending at an angle of 90 degrees to the contact surface 21 is connected to each of adjacent frames by a fastener 19 engaged with and retained by the engaging groove 17. Such connectors 18 are provided in connecting locations of the lower frames 12 and connecting frames 13, connecting locations of the upper frames 11 and connecting frames 13, connecting locations of the lower frames 12 and joining frames 16, and connecting locations of the upper frames 11 and joining frames 16. Each of the lower frames 12, upper frames 11, connecting frames 13 and joining frames 16, as illustrated, desirably has a fixed width perpendicular to the longitudinal direction, from one end to the other end.

To describe the frames further, each of the lower frames 12, upper frames 11, connecting frames 13 and joining frames 16 is formed of an aluminum frame material which is an aluminum extrusion product. This aluminum frame material is rectangular when seen in vertical section (i.e. seen in the longitudinal direction), and has an engaging groove 17 formed in each of the four surfaces to have a back portion broader than an entrance portion. All of these frames have the same sectional shape including the engaging grooves 71, and have a central line FC (FIG. 8(B)) extending longitudinally of the frames. The sectional shape of the frames is in rotation symmetry with respect to this central line FC. The entrance of each engaging groove 71 has a set thickness D, and the shortest distance W between two adjoining engaging grooves is larger than the set thickness D. The shortest distance W between two adjoining engaging grooves desirably is 5% or more of length L of one side of each frame. Each frame has a plurality of cylindrical bores TB formed over the full length from one end to the other end of the frame. One of the bores TB desirably includes the central line FC. The other bores TB desirably are formed adjacent the respective corners of the rectangular frame. Therefore, each engaging groove 71 is disposed between two bores TB when seen in the longitudinal direction. These bores TB contribute toward lightness of the frames.

As shown in FIG. 7, each connector 18 includes, integrally connected together, one contact surface 20, the other contact surface 21 perpendicular to the one contact surface 20, and a reinforcing rib 22 extending between these contact surfaces 20 and 21. Each of the contact surfaces 20 and 21 has a bolt receiving bore 24 formed therein for receiving a fastening bolt 23. The contact surfaces 20 and 21 of the connector 18 are placed in abutment with surfaces, extending perpendicular to each other, of the frames to be connected, and fastened with bolts 23 and nuts 25 to connect the frames together. That is, in all of the connecting locations of the lower frames 12 and connecting frames 13, connecting locations of the upper frames 11 and connecting frames 13, connecting locations of the lower frames 12 and joining frames 16, and connecting locations of the upper frames 11 and joining frames 16, the connectors 18 are placed in abutment with adjoining frames, and connected to the adjoining frames by the bolts 23 and nuts 25 acting as fasteners engaged and retained in the engaging grooves 17, thereby connecting the frames together.

FIG. 7 shows a connection between an upper frame 11 and a connecting frame 13. The contact surfaces 20 and 21 are placed in contact with the surfaces, extending perpendicular to each other, of the upper frame 11 and connecting frame 13. Nuts 25 are placed and retained in the large back portions of the engaging grooves 17 formed in the upper frame 11 and connecting frame 13. Bolts 23 are inserted through the bolt receiving bores 24 to join tight with the nuts 25, thereby connecting the upper frame 11 and connecting frame 13 formed of the aluminum frame material.

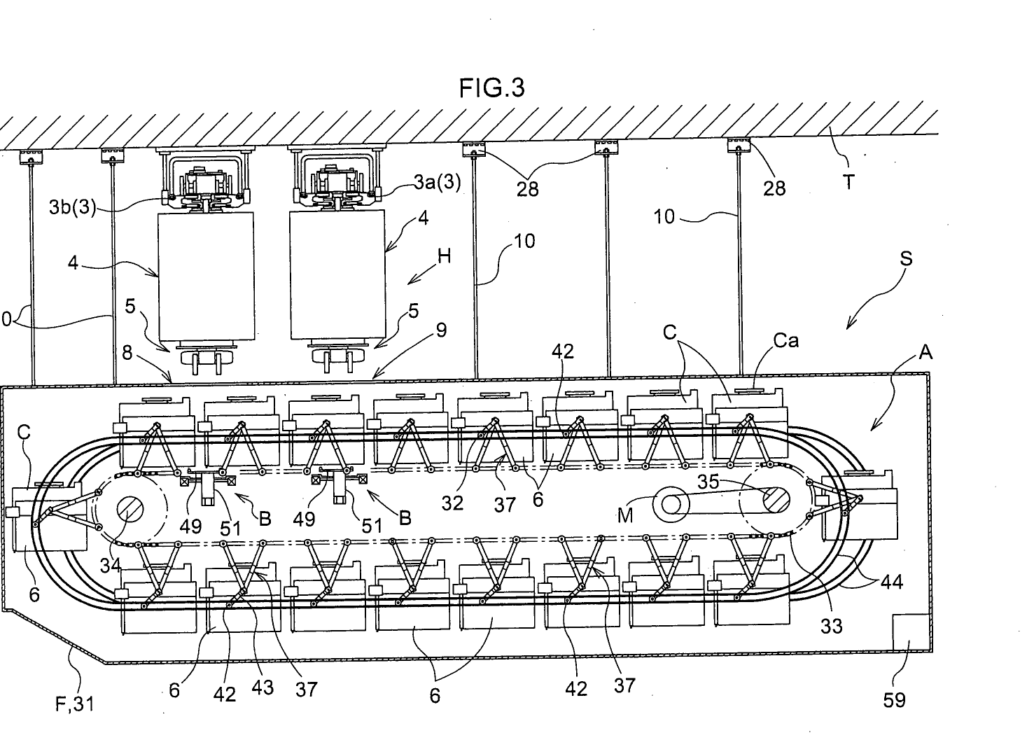

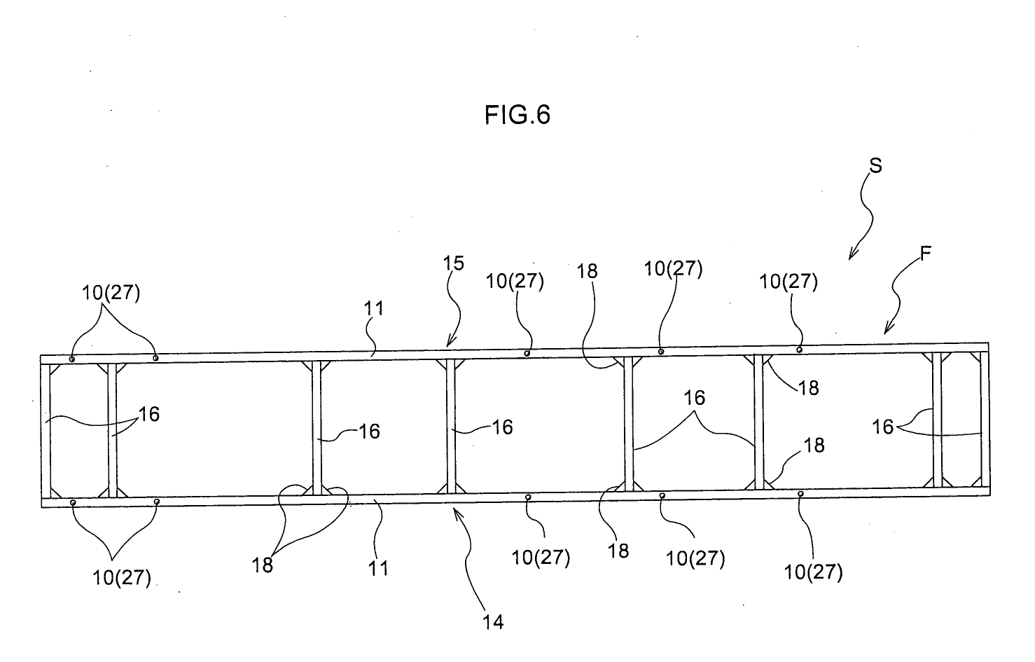

The upper frames 11 have receiving bores 27 formed therein for vertically receiving the hanger bolts 10 acting as elongate supports for suspending and supporting the lower frames 12. More particularly, as shown in FIGS. 6 and 8(A), the upper frames 11 have receiving bores 27 of appropriate size formed in positions thereof corresponding to positions of the hanger bolts 10 (a total of ten hanger bolts being provided in this embodiment) for vertically receiving the hanger bolts 10. The hanger bolts 10 are attached to extend through these receiving bores 27. As shown in FIG. 3, the hanger bolts 10 have upper ends thereof fixed to the ceiling T through brackets 28.

As shown in FIGS. 5, 8 and 9, the lower ends of the hanger bolts 10 are connected to the lower frames 12 through brackets 29. These brackets 29 have a substantially channel-shaped section as seen longitudinally of the lower frames 12, and have a large width in the longitudinal direction of the lower frames 12. The lower end of each hanger bolt 10 is passed through an upper surface 29a of the bracket 29, and fastened thereto from above and below by nuts 30. On the other hand, the lower surface 29b of the bracket 29 is placed in abutment with the upper surface of the lower frame 12, and is connected thereto with the fastener 19 consisting of the bolt 23 and nut 25, as in the connection of the connector 18. Four such fasteners 19 are arranged longitudinally of each lower frame 12 to increase supporting strength in the connecting locations of the brackets 29 and lower frames 12 which receive the weight of the article storage apparatus S.

Thus, the lower frames 12 are suspended and supported by the hanger bolts 10 extending through the receiving bores 27 formed in the upper frames 11. This construction can contain the hanger bolts 10 in an outside dimension in the transverse direction of the article storage apparatus S, thereby realizing a very compact dimension in the transverse direction. Moreover, the weight of the article storage apparatus S is supported by the plurality of hanger bolts 10 through the lower frames 12. No major load is applied to the connecting locations of the upper frames 11 and connecting frames 13, for example.

As shown in FIGS. 2 and 3, the article storage apparatus S includes a casing 31 that surrounds the frame structure F to divide off the approximately rectangular parallelepiped article storage space defined by the frame structure F. The casing 31 houses a pair of right and left endless rotating chains 32 horizontally spaced from each other by a predetermined distance to rotate vertically and along a horizontally long circulation path. A plurality of article storage trays 6 are supported by the right and left endless rotating chains 32 and arranged at intervals longitudinally of the endless rotating chains 32. Thus, a support transporting device A is provided for circulating and transporting the article storage trays 6 in a tandem array.

The construction of the support transporting device A will be described next.

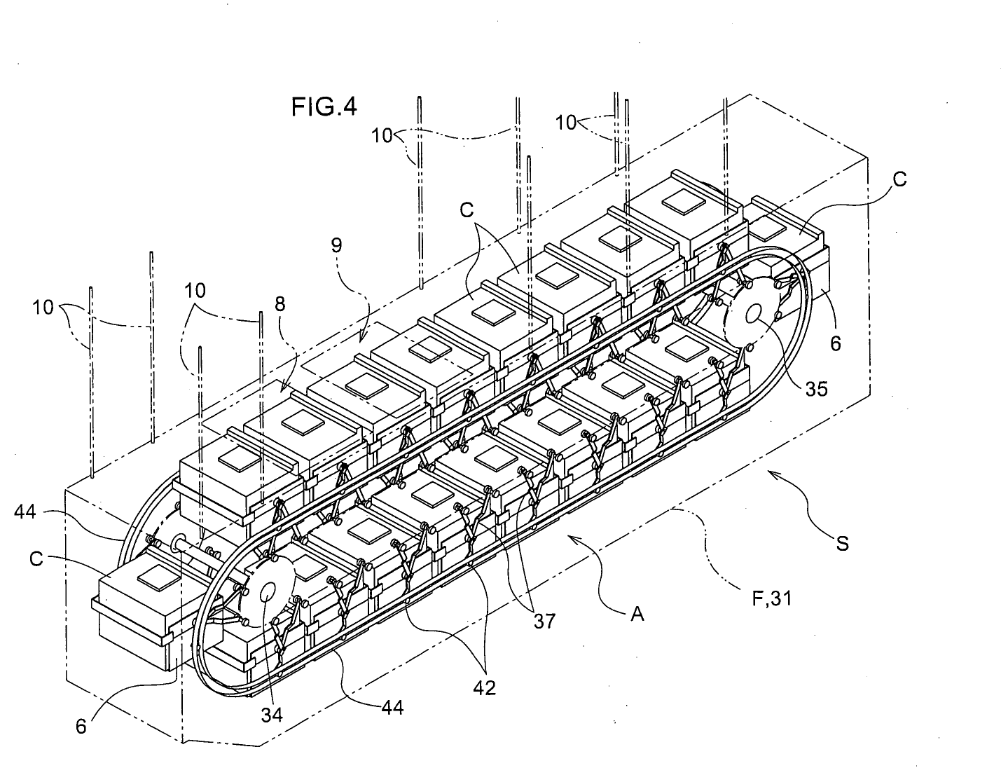

As shown in FIGS. 3, 4, and 9, the endless rotating chains 32 are wound around drive sprockets and driven sprockets arranged as horizontally spaced from each other, respectively. The right and left drive sprockets 33 are mounted on a common drive shaft 35 rotatable by a circulating motor M, to rotate the right and left endless rotating chains 32 synchronously. The driven sprockets are rotatably supported by a support shaft 34. Though not shown, a rotary encoder is provided for detecting amounts of rotation of the drive shaft 35.

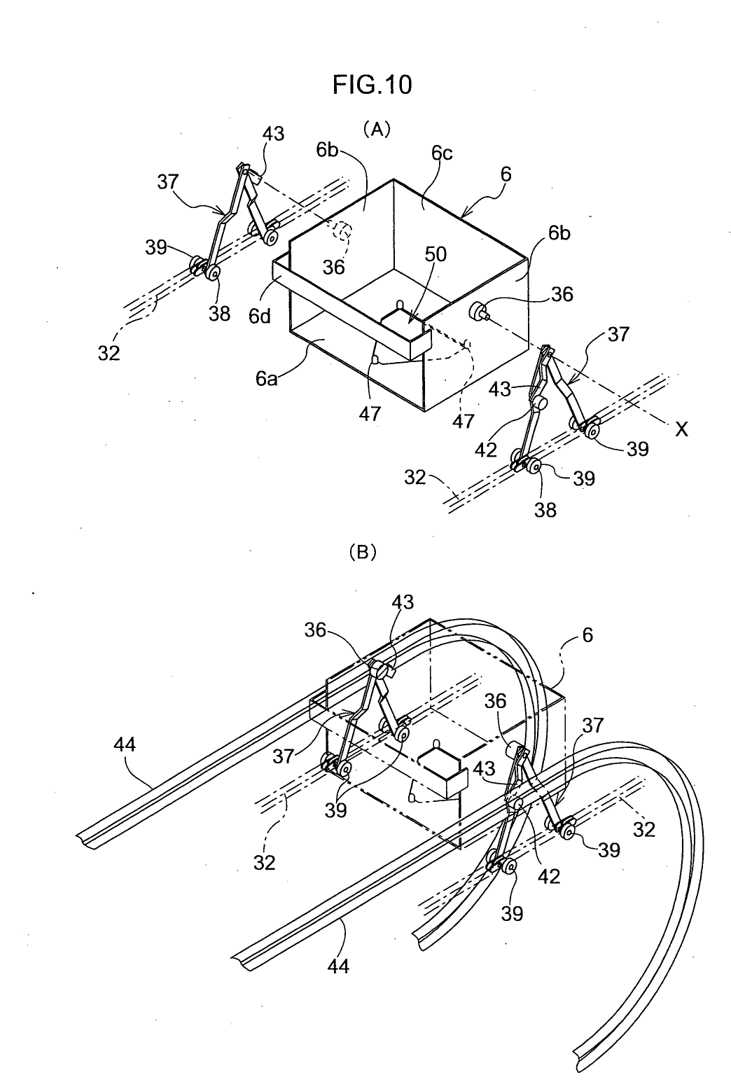

As shown in FIG. 10, each article storage tray 6 includes, as formed integrally together, a bottom plate 6a extending horizontally, a pair of side plates 6b located at right and left ends of the bottom plate 6a, and a rear surface portion 6c located at one side in the direction of transport of the bottom plate 6a. Further, a narrow holding member 6d is provided at the other side in the direction of transport to extend between the pair of side plates 6b.

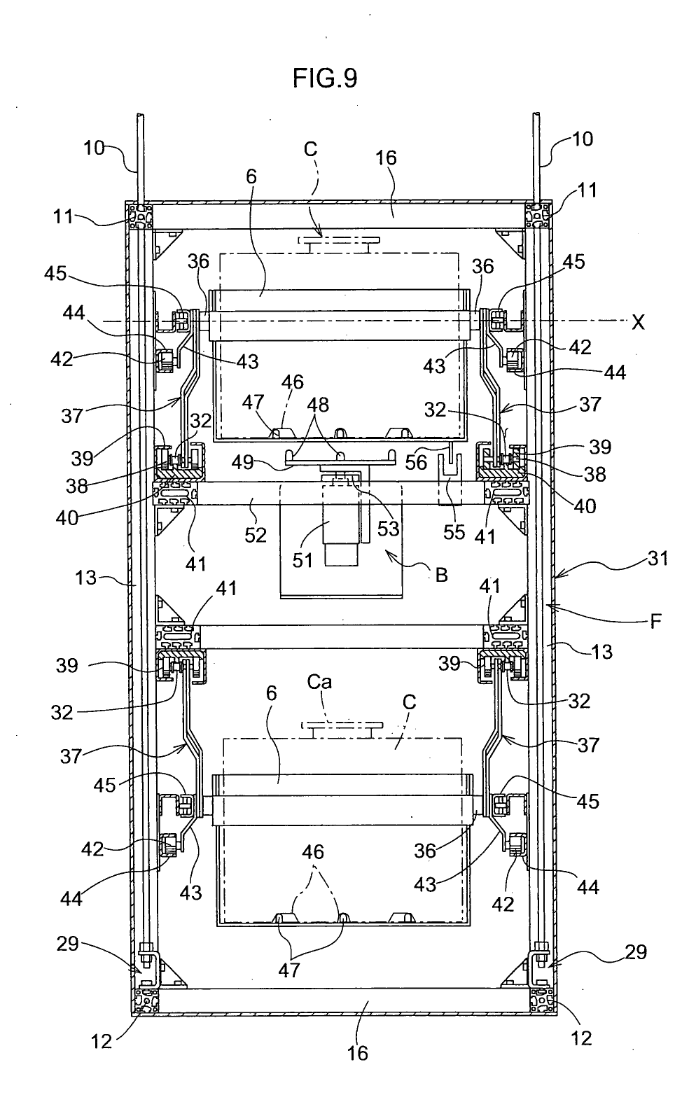

As shown in FIGS. 9 and 10, each article storage tray 6 has pivotal supports 36 formed in upper middle positions in the direction of transport on the pair of side plates 6b. Couplers 37 substantially V-shaped in side view are pivotally connected between the pivotal supports 36 and right and left endless rotating chains 32. The couplers 37 are pivotally connected through support pins 38 to the endless rotating chains 32, and pivotally connected to the article storage tray 6 to be relatively pivotable about a transverse axis X of the pivotal supports 36. The support pins 38 have rollers 39 engaged with and guided along guide rails 40 provided on linear path portions of the endless rotating chains 32. The guide rails 40 are supported by support frames 41 attached to the plurality of connecting frames 13 to extend along the linear path portions of the endless rotating chains 32. Consequently, the article storage trays 6 can move steadily along the linear path portions without the support pins 38, i.e. the connecting locations of the endless rotating chains 32 and couplers 37, wobbling up and down.

A position guide mechanism is provided for maintaining each article storage tray 6 in a substantially horizontal position when the article storage tray 6 is transported in circulation along the transport path of right and left endless rotating chains 32. That is, each article storage tray 6 has, connected to the right and left sides thereof, roller support arms 43 supporting guide rollers 42 attached to distal ends thereof, the roller support arms 43 being rockable with the article storage tray 6 about the transverse axis X. Endless guide rails 44 for engaging and guiding the guide rollers 42 are arranged laterally of the right and left endless rotating chains 32 to extend substantially along the transport path of the endless rotating chains 32.

As shown in FIGS. 3 and 10, when each article storage tray 6 is in the horizontal position, the roller support arms 43 provided on the right and left sides of the article storage tray 6 assume oblique positions inclined in opposite directions from the vertical by a set angle. The right and left guide rails 44 are shaped to guide and maintain each article storage tray 6 in the horizontal position for supporting an article storage container C when the article storage tray 6 is transported in circulation along the transport path of the right and left endless rotating chains 32. Thus, with the guide rollers 42 guided by the guide rails 44, even when the right and left endless rotating chains 32 turn arcuately, each article storage tray 6 is guided to maintain the horizontal posture while supporting the article storage container C. Numeral 45 in FIG. 9 denotes restricting guides for restricting swing motion in the transverse direction of the article storage trays 6.

As shown in FIG. 2, the casing 31 of each article storage apparatus S has, formed in the upper surface thereof, a deposition port 8 for the article transport device H to deposit the article storage containers C on the article storage trays 6, and a delivery port 9 for the article transport device H to deliver the article storage containers C from the article storage trays 6.

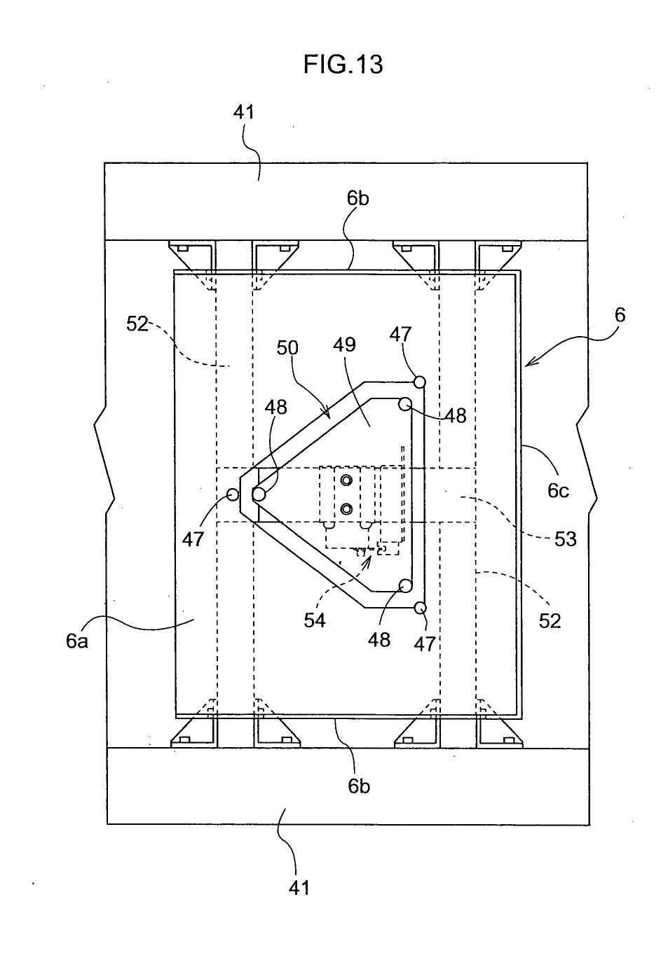

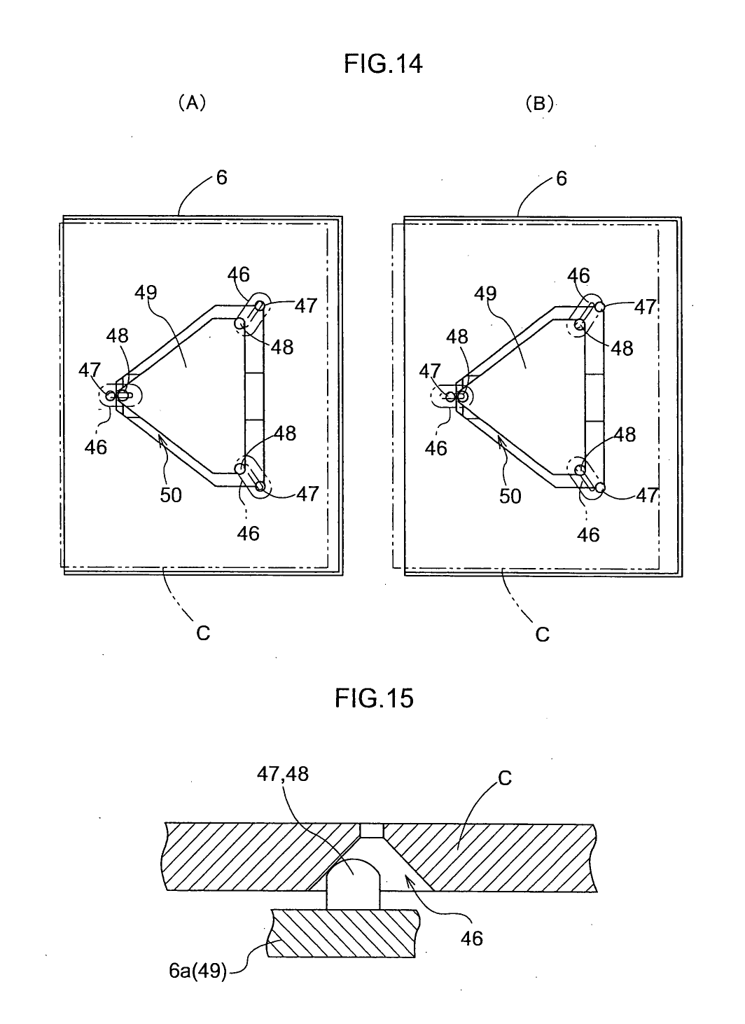

As shown in FIGS. 14 and, 15, each article storage container C has three positioning bores 46 formed at appropriate intervals in the bottom surface thereof, the bores 46 being shaped to flare toward its entrance. On the other hand, as shown in FIGS. 13, 14 and 15, each article storage tray 6 has three positioning projections 47 formed on the bottom plate 6a acting as support surface for engaging the positioning bores 46. As noted above, the positioning bores 46 are shaped to flare toward the entrance. To put it conversely, the positioning bores 46 are sloped to taper inwardly. Thus, as shown in FIG. 15, each positioning projection 47 engages a corresponding one of the positioning bores 46 as guided by the slope even when slightly displaced from the center of the bore 46. When the three positioning projections 47 fit deep into the positioning bores 46 corresponding thereto, a relative horizontal position between the article storage container C and article storage tray 6 is adjusted always to be substantially the same.

In this way, the relative position between the article storage container C and article storage tray 6 may be regulated accurately. However, when the endless rotating chains 32 are rotated to locate one of the article storage trays 6 in a depositing position corresponding to the deposition port 8 or a delivery position corresponding to the delivery port 9, the article storage tray 6 can be somewhat displaced from a proper position suitable for a depositing or delivery operation of the article transport device H. Such an inconvenience can arise from play between the guide rollers 42 and guide rails 44 or a deviation of the weight of article storage containers C. The depositing position corresponding to the deposition port 8 and the delivery position corresponding to the delivery port 9 correspond to the depositing and delivery positions for the article transport device H to carry out depositing and delivery operations.

To cope with the above situation, this article storage apparatus S has a mechanism for positioning the article storage containers to enable the article transport device H to carry out depositing and delivery operations reliably.

Specifically, a positioning member 49 has a plurality of position correcting projections 48 for engaging a plurality of position correcting bores formed in the bottom of each article storage container C to flare toward the entrance. The positioning member 49 is installed in the position corresponding to the depositing or delivery position to be movable upward to receive and support an article storage container C placed on the article storage tray 6 located in the depositing or delivery position, and is movable downward to transfer an article storage container C placed on the positioning member 49 to the article storage tray 6 located in the depositing or delivery position. The article transport device H loads and unload the article storage container C on/from the positioning member 49 in the raised position. In this embodiment, the positioning bores and position correcting bores are integrated into one engaging slot. That is, the positioning bores 46 for adjusting position relative to the article storage trays 6 are used also as the position correcting bores acting on by the positioning member 49.

A specific construction for positioning the article storage containers C will be described hereinafter.

As shown in FIG. 3, a positioning control mechanism B is provided in each of the depositing position and delivery position serving as the depositing and delivery positions. The two positioning control mechanisms B have the same construction. The positioning control mechanism B provided in the depositing position will be described hereinafter, and description of the one in the delivery position will be omitted.

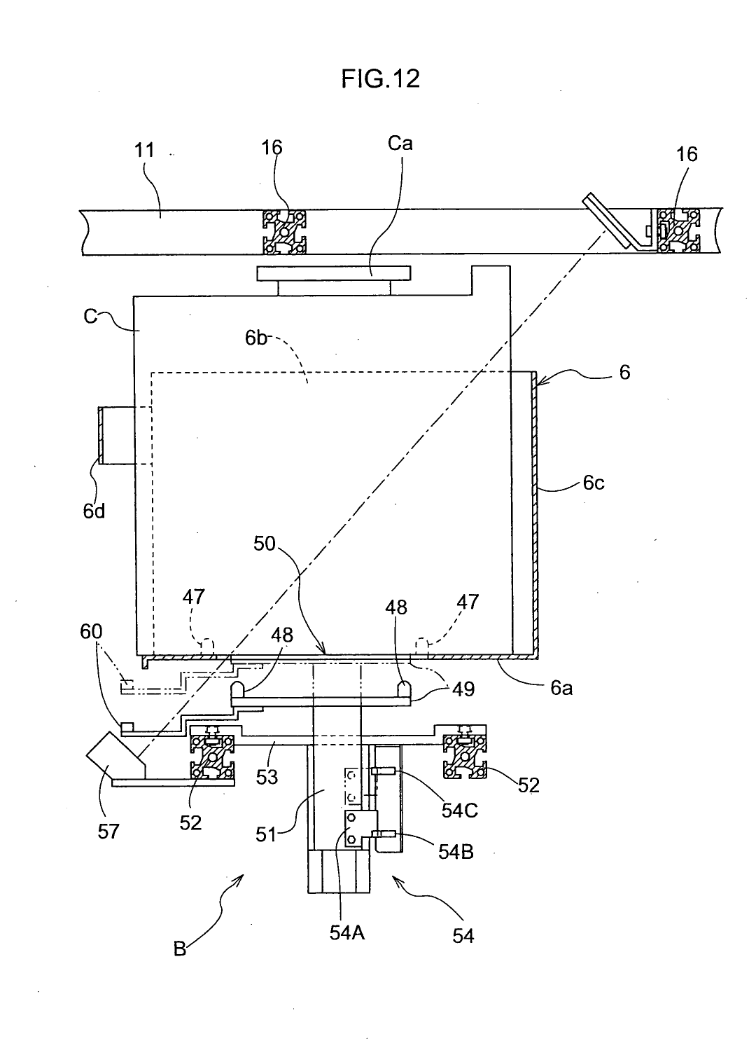

As shown in FIG. 13, the bottom plate 6a of each article storage tray 6 has an approximately triangular receiving bore 50 formed in a central portion thereof. The positioning projections 47 noted hereinbefore project upward from adjacent the respective corners of the triangle of the receiving bore 50. As shown in FIG. 12, the positioning control mechanism B includes the positioning member 49 which can vertically extend through the receiving bore 50 formed in the bottom plate 6a of the article storage tray 6 located in the depositing position, and an electromotive lift mechanism 51 for moving the positioning member 49 between a retracted position below the bottom plate 6a of the article storage tray 6 and an upper position slightly above the bottom plate 6a of the article storage tray 6.

As shown in FIG. 13, a pair of mounting frames 52 are connected between the right and left support frames 41. A support deck 53 is connected between the pair of mounting frames 52. The electromotive lift mechanism 51 is fixed to and supported by the support deck 54. Thus, the electromotive lift mechanism 51 is fixedly supported by the frame structure F, and the position of positioning member 49 when operated in the upper position is controlled accurately irrespective of the position of article storage tray 6.

The positioning member 49 has an approximately triangular outside shape slightly smaller in plan view than the receiving bore 50. A total of three position correcting projections 48 are formed adjacent the respective corners of this triangle. The electromotive lift mechanism 51 contains an electric motor and a screw feed mechanism not shown, for moving the positioning member 49 by a set amount between the retracted position and upper position.

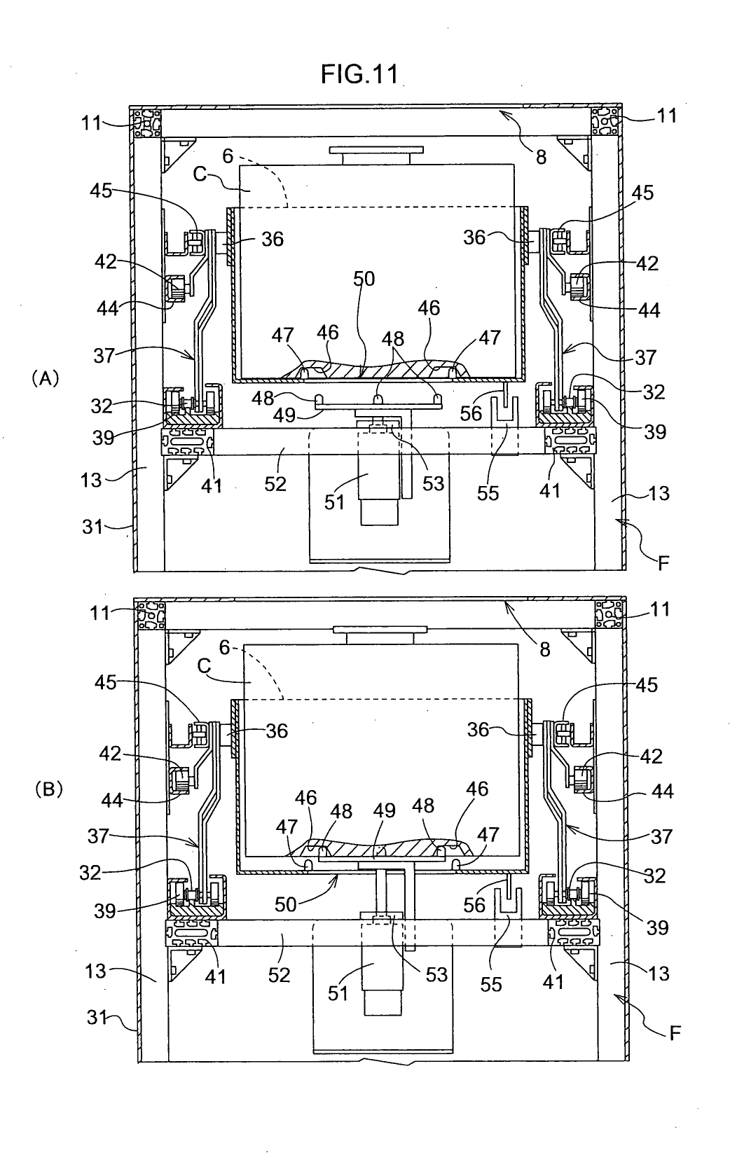

When the electromotive lift mechanism 51 is operated to move the positioning member 49 to the retracted position as shown in FIG. 11(A), the positioning member 49 is retracted below the bottom plate 6a of the article storage tray 6. When the positioning member 49 is moved to the upper position as shown in FIG. 11(B), the positioning member 49 is located above the bottom plate 6a of the article storage tray 6, to receive the article storage container C from the article storage tray 6.

In this way, the positioning member 49 raised from the retracted position to the upper position receives the article storage container C from the article storage tray 6. At this time, as at the time of engagement between the positioning bores 46 and positioning projections 47, as shown in FIGS. 14 and 15, each positioning projection 48 engages a corresponding one of the positioning bores 46 as guided by the slope even when slightly displaced from the center of the bore 46. When the three positioning projections 48 fit deep into the positioning bores 46 corresponding thereto, a relative horizontal position between the article storage container C and positioning member 49 is adjusted always to be substantially the same.

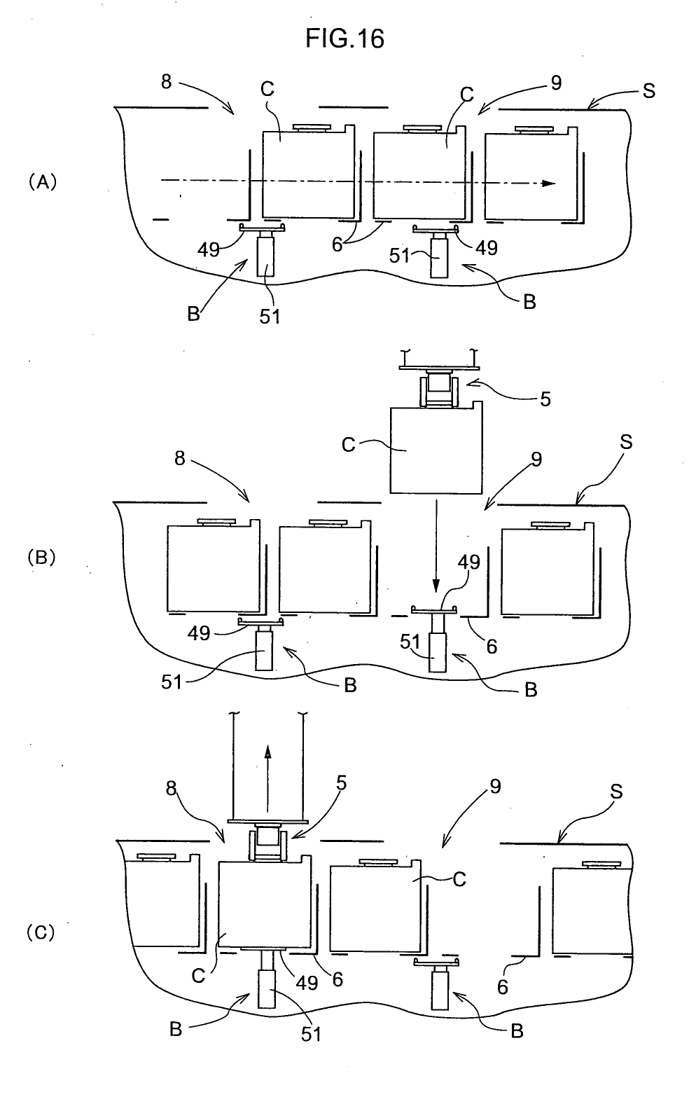

As shown in FIG. 16(C), the article storage container C placed on and supported by the positioning member 49 is gripped and picked up by the article transport device H. When receiving an article storage container C from the article transport device H, as shown in FIGS. 11 and 16(B), the positioning member 49 is placed in the upper position to receive the article storage container C from the article transport device H. Then, the positioning member 49 is lowered to pass the article storage container C on to an article storage tray 6.

As shown in FIG. 12, a position detecting device 54 is disposed adjacent the electromotive lift mechanism 51 for detecting that the positioning member 49 is operated to the retracted position or to the upper position. The positioning member 49 has a plate 54A for position detection vertically movable with the positioning member 49. A lower limit position detecting element 54B and an upper limit position detecting element 54C are supported by the support deck 53 for detecting a lower limited position and an upper limit position based on presence or absence of the plate 54A.

As shown in FIG. 9, a position detecting sensor 55 of the transmitted light type is provided for detecting that an article storage tray 6 is located in the depositing position by detecting presence of a detected plate 56 depending from the lower surface of the bottom plate 6a. As shown in FIG. 12, an article sensor 57 of the reflected light type is also provided for detecting presence or absence of an article storage container C.

As shown in FIG. 1, a main controller 58 is provided for controlling operation of the article transport device H, and storage controllers 59 for controlling operation of the article storage apparatus S. These main controller 58 and storage controllers 59 are constructed to communicate control information therebetween.

Next, details of the controls by the main controller 58 and storage controllers 59 and operations of the article transport device H and article storage apparatus S will be described.

Though not shown, each article storage container C has an IC tag (i.e. an RFID tag) attached thereto for transmitting container identification information such as a lot number to a predetermined range. As shown in FIG. 12, each article storage apparatus S has a receiver 60 for receiving container identification information transmitted from the IC tag of an article storage container C newly placed on the article storage tray 6 located under the deposition port 8. Each of the article storage trays 6 has tray identification information (e.g. a tray number) set beforehand using an IC tag as noted above, for identifying each article storage tray 6.

The storage controllers 59 manage a correspondence relation between positions on the circulating path of the plurality of article storage trays 6 and the tray identification information on the article storage trays 6 based on the detection information from the rotary encoders, a correspondence relation between the tray identification information on the article storage trays 6 carrying article storage containers C and container identification information on the article storage container C currently placed on the article storage trays 6 based on the information received by the receivers 60, and tray identification information on article storage trays 6 not loaded with article storage containers C. The storage controllers 59 also manage positions of the positioning members 49 based on detection information from the position detecting devices 54, to control operation of electromotive lift mechanisms 51.

The main controller 58, upon receipt of a container output command from a processing unit controller (not shown) which controls operation of a processing unit 1, transmits a depositing command to the storage controller 59 of article storage apparatus S that should store the article storage container C corresponding to the container output command. Then, the main controller 58 controls the article transport device H to move one of the article transport vehicles 4 to a target stopping position corresponding to the support table 1a of the processing unit 1 having transmitted the container output command, stop the article transport vehicle 4 in the target stopping position, operate the article gripper 5 to grip and pick up the article storage container C from the support table 1a, then move the article transporting vehicle 4 to a target stopping position corresponding to the deposition port 8 of the article storage apparatus S that should store the article storage container C.

In the absence of any command from the main controller 58, the storage controller 59 executes an empty tray call process for determining the position of an unloaded article storage tray 6 nearest to the deposition port 8, and controlling the circulating motor M to rotate the endless rotating chains 32 in a direction that provides the shorter path from the unloaded article storage tray 6 to the deposition port 8, and locate the unloaded article storage tray 6 in the depositing position. The storage controller 59 stands by with the unloaded article storage tray 6 in the depositing position, and the positioning member 49 of the positioning control mechanism in the depositing position operated to the upper position.

Upon receipt of a depositing command from the main controller 58, the storage controller 59 transmits to the main controller 58 deposition ready information indicating the state of the unloaded article storage tray 6 standing still in the depositing position. Upon receipt of the deposition ready information from the storage controller 59, the main controller 58 lowers and transfers the article storage container C gripped by the article gripper 5 in the depositing position to the positioning member 49 in the upper position.

Further, when the article storage container C has been transferred in the depositing position to the positioning member 49 and the presence of the article storage container C is confirmed by the article sensor, the storage controller 59 lowers the positioning member 49. By the lowering of the positioning member 49, the article storage container C is transferred to the article storage tray 6 located in the depositing position. In this way, the article storage container C is newly placed on the empty article storage tray 6 located in the depositing position. When the receiver 60 receives the identification information on the article storage container C, the storage controller 59 manages a correspondence relation between the tray identification information on the article storage tray 6 located in the depositing position and the container identification information on the article storage container C placed thereon.

Upon receipt of a container input command from a processing unit controller and identification information on an article storage container C to be inputted, the main controller 58 transmits a delivery command and the identification information on an article storage container C to be delivered, to the storage controller 59 of article storage apparatus S storing the article storage container C matching the identification information received, moves one of the article transport vehicles 4 to a target stopping position corresponding to the delivery port 9 of the article storage apparatus S, and stops the article transport vehicle 4 in the target stopping position.

Upon receipt from the main controller 58 of the delivery command and the identification information on the article storage container C to be delivered, the storage controller 59 executes a delivery tray call process for determining the position of the article storage tray 6 storing the article storage container C matching the identification information received, and controlling the circulating motor M to rotate the endless rotating chains 32 in a direction that provides the shorter path from the article storage tray 6 to the delivery port 9, and locate the article storage tray 6 in the delivery position. Further, the storage controller 59 moves the positioning member 49 of the positioning control mechanism B in the delivery position to the upper position, to transfer the article storage container C from the article storage tray 6 to the positioning member 49 being raised. Then, the storage controller 59 transmits delivery ready information indicating the state of the article storage container C to be delivered standing still in the position corresponding to the delivery port 9.

Upon receipt of the delivery ready information from the storage controller 59, the main controller 58 causes the article gripper 5 to grip and pick up the article storage container C from the positioning member 49, then moves the article transport vehicle 4 to a target stopping position corresponding to the support table 1a of the processing unit 1 having transmitted the container input command, stops the article transport vehicle 4 in the target stopping position, and places the article storage container C gripped by the article gripper 5 on the support table 1a of the processing unit 1.

The storage controller 59, when a depositing command is received from the main controller 58 in a state of no unloaded article storage tray 6 being located in the depositing position, first executes the empty tray call process, and thereafter transmits deposition ready information to the main controller 58. The storage controller 59 executes the delivery tray call process when a delivery command is received during execution of the empty tray call process initiated by neither a delivery command nor a depositing command.

### Other Embodiments

(1) In the foregoing embodiment, each of the lower frames, upper frames, connecting frames and joining frames is rectangular when seen in vertical section, and has an engaging groove formed in each of the four surfaces to have a back portion broader than an entrance portion. It is possible to use frames having no such engaging grooves.

(2) In the foregoing embodiment, the lower frames and upper frames are connected to the connecting frames to form a pair of right and left side frames which are interconnected by a plurality of joining frames extending transversely. As a replacement for such construction, only one side frame may be constructed by connecting the lower frames and upper frames to the connecting frames, with the support transporting device installed laterally of the side frame.

(3) In the foregoing embodiment, the article storage apparatus is suspended from the ceiling by a plurality of hanger bolts. As a replacement for such construction, for example, the article storage apparatus may be suspended by hanger bolts from a mobile body supported to be movable along a guide rail installed on the ceiling. That is, the mobile body is movable horizontally along the guide rail while suspending the article storage apparatus through hanger bolts. Besides such construction, the article storage apparatus may be installed on the floor, or may be placed on and supported by an overhang structure supported by a wall to project horizontally from the wall.

(4) In the foregoing embodiment, the article storage apparatus transports, in circulation in a tandem array, a plurality of supports supporting article storage containers vertically along the circulatory moving path rotatable about transverse axes. Instead, the plurality of supports supporting article storage containers may be circulated and transported in a tandem array along a horizontal circulatory moving path rotatable about vertical axes.

(5) The elongate supports used herein may be rope-like objects manufactured by bundling a plurality of fibers of nylon or other known material.

What is claimed is:

1. A frame system for an article storage apparatus which defines an article storage space therein, comprising:
a first upper frame extending horizontally;
a first lower frame extending horizontally; and
at least one first connecting frame extending vertically and interconnecting said first upper frame and said first lower frame, said at least one first connecting frame being connected to said first upper frame with the at least one first connecting frame abutting a lower surface of said first upper frame, and connected to said first lower frame with the at least one first connecting frame abutting an upper surface of said first lower frame;
said first upper frame having receiving bores formed therein through which elongate supports extend vertically when said elongate supports are attached to said first lower frame to suspend the first lower frame.

2. A frame system as defined in claim 1, further comprising:
a second upper frame extending horizontally;
a second lower frame extending horizontally;
at least one second connecting frame extending vertically and interconnecting said second upper frame and said second lower frame, said at least one second connecting frame being connected to said second upper frame with the at least one second connecting frame abutting a lower surface of said second upper frame, and connected to said second lower frame with the at least one second connecting frame abutting an upper surface of said second lower frame;
said second upper frame having receiving bores formed therein through which elongate supports extend vertically when said elongate supports are attached to said second lower frame to suspend the second lower frame; and
joining frames extending transversely for joining a right side frame formed by connecting said first lower frame and said first upper frame to said at least one first connecting frame, and a left side frame formed by connecting said second lower frame and said second upper frame to said at least one second connecting frame;
wherein each of said first and second lower frames, said first and second upper frames, said at least one first connecting frame and said at least one second connecting frame is formed elongate.

3. A frame system as defined in claim 2, wherein:
each of said first and second lower frames, said first and second upper frames, said at least one first connecting frame, said at least one second connecting frame and said joining frames is rectangular when seen in a longitudinal direction thereof, and has an engaging groove formed in each of four surfaces thereof, each of said engaging groove having an interior space broader than an entrance thereof, and
connectors, each having a first contact surface and a second contact surface extending perpendicular to said first contact surface, are arranged in contact with adjacent frames and connected to each of the adjacent frames by a fastener engaged with corresponding one of said engaging grooves, in at least some of a connecting location between said first lower frame and said at least one first connecting frame, a connecting location between said second lower frame and said at least one second connecting frame, a connecting location between said first upper frame and said at least one first connecting frame, a connecting location between said second upper frame and said at least one second connecting frame, connecting locations between said first lower frame and said joining frames, connecting locations between said second lower frame and said joining frames, connecting locations between said first upper frame and said joining frames, and connecting locations between said second upper frame and said joining frames.

4. A frame system as defined in claim 2, wherein:
each of said first and second lower frames, said first and second upper frames, said at least one first connecting frame, said at least one second connecting frame and said joining frames is rectangular when seen in a longitudinal direction thereof, and has an engaging groove formed in each of four surfaces thereof, each of said engaging groove having an interior space broader than an entrance thereof, and
connectors, each having a first contact surface and a second contact surface extending perpendicular to said first contact surface, are arranged in contact with adjacent frames and connected to each of the adjacent frames by a fastener engaged with corresponding one of said engaging grooves, in all of a connecting location between said first lower frame and said at least one first connecting frame, a connecting location between said second lower frame and said at least one second connecting frame, a connecting location between said first upper frame and said at least one first connecting frame, a connecting location between said second upper frame and said at least one second connecting frame, connecting locations between said first lower frame and said joining frames, connecting locations between said second lower frame and said joining frames, connecting locations between said first upper frame and said joining frames, and connecting locations between said second upper frame and said joining frames.

5. A frame system as defined in claim 3, wherein said entrance of each said engaging grooves has a predetermined thickness, and a shortest distance between two adjacent engaging grooves is greater than said predetermined thickness.

6. A frame system as defined in claim 3, wherein all of said first and second lower frames, said first and second upper frames, said at least one first connecting frame, said at least one second connecting frame and said joining frames have an identical sectional shape including said engaging grooves.

7. A frame system as defined in claim 3, wherein said first and second lower frames, said first and second upper frames, said at least one first connecting frame, said at least one second connecting frame and said joining frames have an identical sectional shape including said engaging grooves and a central point, said sectional shape having a rotation symmetry with respect to said central point.
